(19) United States
(12) Patent Application Publication
(10) Pub. No.: US 2007/0059900 A1
(43) Pub. Date: Mar. 15, 2007

(54) MULTI-STEP DEPOSITING PROCESS

(76) Inventors: Chien-Hsing Lai, Kao-Hsiung Hsien (TW); Chun-Yi Wang, Chang-Hua Hsien (TW); Ming-Cheng Chen, Kao-Hsiung City (TW); Brady Houng, Kao-Hsiung Hsien (TW)

Correspondence Address: NORTH AMERICA INTELLECTUAL PROPERTY CORPORATION, P.O. BOX 506, MERRIFIELD, VA, 22116, US

(21) Appl. No.: 11/162,536

(22) Filed: Sep. 14, 2005

(51) Int. Cl. H01L 21/762

(52) U.S. Cl. 438/435; 438/694; 438/761

(57) ABSTRACT

The present invention provides a multi-steps depositing process. The process provides a substrate having at least a shallow trench, and then performs a first high density plasma chemical vapor deposition (HDP CVD) to form a first dielectric layer on the substrate and a surface of the shallow trench. A partial etching process is performed to etch the first dielectric layer, and a passivation process is performed. Finally, a second HDP CVD is performed to form a second dielectric layer on the first dielectric layer and fill the shallow trench.

### BACKGROUND OF THE INVENTION

1. Field of the Invention

The invention relates to a multi-step depositing process, and more particularly, to a multi-step depositing process with better gap-fill ability.

2. Description of the Prior Art

In semiconductor processes, in order to provide good electrical isolation and to prevent short-circuiting between electric devices on a wafer, a localized oxidation isolation (LOCOS) process, or a shallow trench isolation (STI) process is used to isolate and protect devices. Since the field oxide layer of the LOCOS process consumes a good deal of area on the wafer, and a bird's beak can occur when growing the field oxide, a high density plasma chemical vapor deposition (HDP CVD) is typically used to form an STI in the semiconductor processes when the line width is below 250 nm.

The HDP CVD is normally used to form the dielectric layer of the STI structure. This kind of HDP silicon oxide layer formed by the HDP CVD method has excellent ladder covering ability and good conformity, in comparison to the usual CVD silicon oxide layer that has the problem of high aspect ratio of severe topography leading to filling difficulty. However, due to a decreasing of the line width, even though the HDP CVD can effective fill the shallow trench of each device or the gap of metals in a bigger line width, in the 90 nm process, the HDP CVD easily overhangs on an opening of the shallow trench, and thus causes problems, such as uneven coverage of voids or seams, or preventing the trenches from being filled.

Please refer to FIG. 1 to FIG. 3 that are schematic diagrams of an HDP CVD process according to prior art. As shown in FIG. 1, a substrate 10 has at least a shallow trench 12. A depositing process is performed to deposit dielectric materials 14 on the substrate 10 and the shallow trench 12 by HDP CVD. As shown in FIG. 2, the dielectric materials 14 are continuously deposited on the substrate 10 and the shallow trench 12. Although the HDP CVD has a chemical vapor deposition and a physical sputter deposition at the same time, due to small line widths, an etching rate of the physical sputter deposition is slower than an etching rate of the chemical vapor deposition so that the shallow trench 12 has an overhang 16. Finally, as shown in FIG. 3, after finishing depositing the dielectric materials 14, the shallow 12 has voids 18 so that utilizing chemical mechanical polishing (CMP) to planarize results in remnants unevenly covering the voids or seams and preventing the trenches from being filled.

Therefore, larger plasma power is applied to dissociate the molecules of reactant gases, to improve the gap-fill ability and prevent the openings of the shallow trenches from being clogged. When larger plasma power is applied to perform the oxide deposition process of the HDP CVD, stronger collisions between particles cause the oxide layer on the wall to strip off more easily. As a result, there is need for an improved method to resolve the clogged shallow trench opening and the particle issue in small critical dimension processes.

### SUMMARY OF THE INVENTION

It is therefore a primary objective of the claimed invention to provide a multi-step depositing process to solve the above-mentioned problems.

According to the claimed invention, a multi-step depositing process provides a substrate having at least a shallow trench and then performs a first high density plasma chemical vapor deposition (HDP CVD) to form a first dielectric layer on the substrate and a surface of the shallow trench. A partial etching process is performed to etch the first dielectric layer until an overhang disappear and a passivation process is performed. Finally, a second HDP CVD is performed to form a second dielectric layer on the first dielectric layer and fill the shallow trench.

The present invention multi-step depositing process uses the partial etching process to etch the overhang of shallow trench opening formed in the first HDP CVD process to enlarge the partially closed shallow trench opening. Then, the passivation process is performed to remove particles and the second HDP CVD process is performed to fill the shallow trench. The method can avoid voids in the shallow trench and form a better profile to enhance yield and decrease costs.

These and other objectives of the claimed invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 3 are schematic diagrams of an HDP CVD process according to prior art.

FIG. 4 to FIG. 7 are schematic diagrams of the multi-step depositing process according to the present invention.

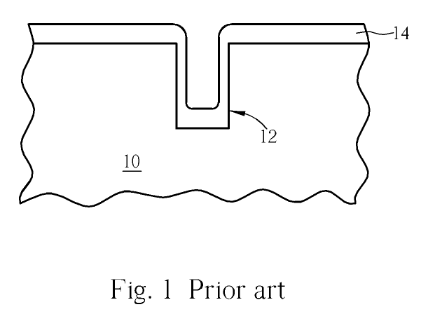

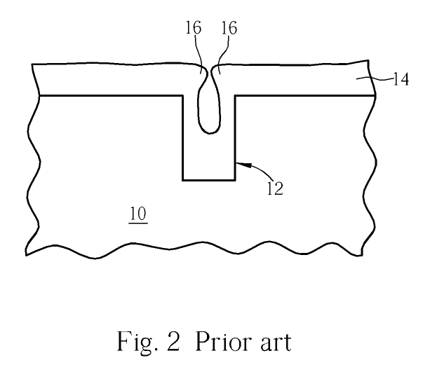

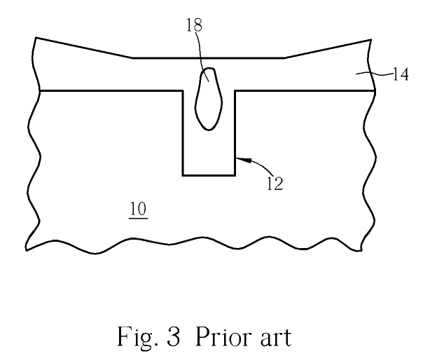

### DETAILED DESCRIPTION

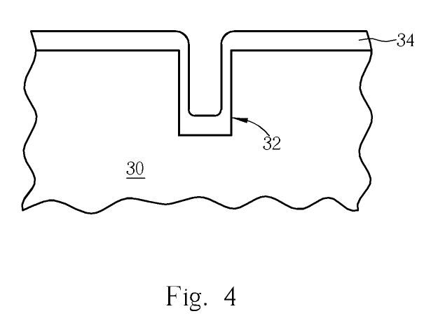

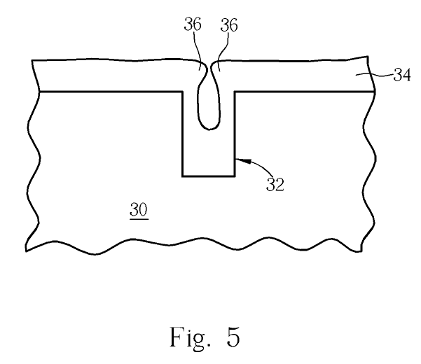

Please refer to FIG. 4 to FIG. 7 that are schematic diagrams of the multi-step depositing process according to the present invention. As shown in FIG. 4, at least one shallow trench 32 is formed in a predetermined area of a substrate 30, such as between an active area of adjacent metal-oxide semiconductors (MOS). The substrate 30 is put in the chamber and then a first HDP CVD is performed to deposit by utilizing nitrogen (N₂), oxide nitride (NₓO_{y}), nitrogen hydride (NₓH_{y}), nitrogen fluoride (NₓF_{y}), oxygen (O₂), helium (He₂), silicide (SiH₄, SiF₄, Si₂H₆, teraethylorthosilicate (TEOS), tetramethylcyclo-tetrasiloxane (TMCTS), octamethylcyclotetrasiloxane (OMCTS), methyl-silane, demethyl-silane, 3MS, 4MS, tetramethyidisiloxane (TMDSO), TMDDSO, dimethydimethoxysilane (DMDMS)), or fluorine (F₂), or a mixture of two or more of the above gases. At the same time, a high frequency radio frequency (HFRF) and a low frequency radio frequency (LFRF) bias are performed to make gases deposited to form a first dielectric layer 34 on a surface of the substrate 30 and the shallow trench 32. As shown in FIG. 5, the first dielectric layer 34 is continuously deposited on the surface of the substrate 30 and the shallow trench 32. When a width of the gap between opposing sides of an overhang 36 in an opening of the first dielectric layer 34 is about 1.5 μm and not yet closed, the depositing process is stopped to prevent forming a void by closing the gap in the overhang 36.

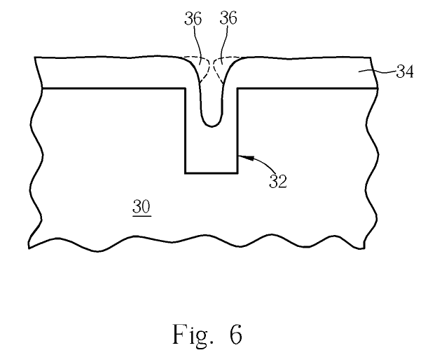

Moreover, as shown in FIG. 6, a partial etching process is performed to etch the over hang 36 of the first dielectric layer 34 by utilizing halogen gases, preferably fluorine gases, such as nitrogen trifluorine (NF₃), so the opening of the first dielectric layer 34 is large. Because the halogen gases react with halogen ions, the NF₃ gases is an example. The NF₃ gases react to fluorine ions (F—), and the fluorine ions filter and remain on the surface of the first dielectric layer 34 and the shallow trench 32 inhibiting the latter implant process and influencing the isolation effect of STI and electrical features of the MOS transistor. Therefore, the present invention utilizes a passivation process to remove fluorine ions by passing hydrogen. The hydrogen reacts with fluorine ions to become hydrogen fluoride, and at the same an air-removal apparatus is used to remove the hydrogen fluoride. Eq. 1 shows the chemical equation for this process.
F→2F⁻
2F^{-+H}₂→2HF Eq.1

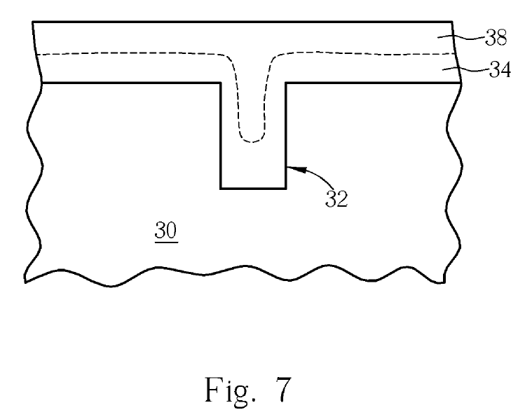

As shown in FIG. 7, then the first dielectric layer 34 is continuously deposited to form second dielectric layer 38 by utilizing a second HDP CVD process using the same gases as was used in the first HDP CVD process, such as nitrogen (N₂), nitrogen oxide (NₓO_{y}), nitrogen hydride (NₓH_{y}), nitrogen fluoride (NₓF_{y}), oxygen (O₂), helium (He₂), silicide (SiH₄, SiF₄, Si₂H₆, teraethylorthosilicate (TEOS), tetramethylcyclo-tetrasiloxane (TMCTS), octamethylcyclotetrasiloxane (OMCTS), methyl-silane, demethyl-silane, 3MS, 4MS, tetramethyidisiloxane (TMDSO), TMDDSO, dimethydimethoxysilane (DMDMS)), or fluorine (F₂), or a mixture of at least two of the above gases. On the other hand, it can be considered that the steps of FIG. 6 to FIG. 7 can be repeated when the second dielectric layer 38 still has an overhang in the second HDP CVD process, meaning that after finishing the second HDP CVD process, the partial etching process, the passivation process, and the second HDP CVD process can be repeated to check that there are no voids and seams in the first dielectric layer 34 of the shallow trench 32. Finally, utilizing CMP polishes the second dielectric layer 38 and an STI process is finished. In other words, after finishing the second HDP CVD process, the second HDP CVD process can still be repeated as the third HDP CVD process, the fourth HDP CVD process, the fifth HDP CVD process, etc.

Besides, each HDP CVD, the partial etching process, and the passivation process is performed in the same chamber by in-situ processing, and the HFRF and LFRF is provided to the chamber to obtain better results. The preferred frequency range of HFRF and LFRF in the first and second HDP CVD process is higher than the range of HFRF and LFRF in the partial etching process and passivation process. On the other hand, the preferred frequency range of HFRF in the passivation process is higher than in the partial etching process.

The multi-step depositing process of the present invention utilizes the partial etching process and the passivation process to effectively prevent overhang 36, formed on the opening of the first dielectric layer 34 in the shallow trench 32 during the first HDP CVD process, from causing voids in the first dielectric layer 34 after planarization. Therefore, when the overhang 36 in the opening of the first dielectric layer is nearly closed in the first HDP CVD process, the partial etching process is performed to etch the overhang 36 and the opening of the first dielectric layer 34 is opened. In addition, in the partial etching process, halogen ions are produced, so the passivation process is performed to form hydrogen halide by passing hydrogen and fluorine, and at the same time the air-removal apparatus removes halide. Because the partial etching process and the passivation process are added, the present HDP CVD process can effectively prevent a clogged shallow trench opening from forming voids and without high plasma power that causes particle pollution.

To sum up, when related to the HDP CVD of prior art, the present invention utilizes the partial etching process and the passivation process to enhance the gap-fill ability of the deposition process and decrease problems such as uneven coverage of voids or seams, preventing the trenches from being filled, and high plasma power collision causing particle pollution, and in addition provides increased yield and decreased costs.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A multi-step depositing process, the multi-step depositing process comprising:
providing a substrate in a chamber, and the substrate having at least a shallow trench;
performing a first high density plasma chemical vapor deposition (HDP CVD) process, and a first dielectric layer formed on the substrate and the shallow trench;
performing a first partial etching process to remove portions of the first dielectric layer;
performing a first passivation process on the first dielectric layer;
performing at least a gapfill process to fill the shallow trench until an overhang disappear; and
performing a second high density plasma chemical vapor deposition process to fill the shallow trench up.

2. The process of claim 1 wherein the gapfill process is a repeated step.

3. The process of claim 1 wherein gases of the first and the second high density plasma chemical vapor deposition process comprise nitrogen (N₂), nitrogen oxide (NₓO_{y}), nitrogen hydride (NₓH_{y}), nitrogen fluoride (NₓF_{y}), oxygen (O₂), helium (He₂), silicide, or fluorine (F₂), or a mixture of at least two of the above gases.

4. The process of claim 1 wherein gases of the first partial etching process comprise halogen gases, and the halogen gases react to form halogen ions in the chamber.

5. The process of claim 4 wherein gases of the first passivation process comprise hydrogen, and the hydrogen reacts with halogen ions to form halogen hydride to remove the halogen ions in the chamber.

6. The process of claim 1 wherein the gapfill process is a thirdhigh density plasma chemical vapor deposition, for forming a second dielectric layer on the first dielectric layer to fill the shallow trench until an overhang disappear.

7. The process of claim 6 wherein gases of the thirdhigh density plasma chemical vapor deposition process comprise nitrogen (N₂), nitrogen oxide (NₓO_{y}), nitrogen hydride (NₓH_{y}), nitrogen fluoride (NₓF_{y}), oxygen (O₂), helium (He₂), silicide, or fluorine (F₂), or a mixture of at least two of the above gases.

8. The process of claim 1 wherein the gapfill process further comprises
performing a third high density plasma chemical vapor deposition to form a second dielectric layer on a surface of the first dielectric layer;
performing a second partial etching process to remove portions of the second dielectric layer; and
performing a second passivation process on the second dielectric layer.

9. The process of claim 8 wherein gases of the third high density plasma chemical vapor deposition process comprise nitrogen (N₂), nitrogen oxide (NₓO_{y}), nitrogen hydride (NₓH_{y}), nitrogen fluoride (NₓF_{y}), oxygen (O₂), helium (He₂), silicide, or fluorine (F₂), or a mixture of at least two of the above gases.

10. The process of claim 1, 6 or 8 wherein a high frequency radio frequency (HFRF) and low frequency radio frequency (LFRF) is provided in the chamber in performing multi-step depositing process.

11. The process of claim 10 wherein a frequency range of the HFRF and the LFRF of the first, the second and the third high density plasma chemical vapor deposition process is higher than a frequency range of the HFRF and the LFRF of the first partial etching process and the first passivation process.

12. The process of claim 9 wherein the frequency range of the HFRF of the first passivation process is higher than the frequency range of the HFRF of the first partial etching process.

13. A multi-step depositing process, the multi-step depositing process comprising:
providing a substrate in a chamber;
performing a first high density plasma chemical vapor deposition (HDP CVD) process, and a first dielectric layer formed on the substrate;
performing a partial etching process to remove portions of the first dielectric layer;
performing a first passivation process on the first dielectric layer to remove portions of the first dielectric layer in the partial etching process; and
performing a second high density plasma chemical vapor deposition.

14. The process of claim 13 wherein gases of the first high density plasma chemical vapor deposition process comprise nitrogen (N₂), nitrogen oxide (NₓO_{y}), nitrogen hydride (NₓH_{y}), nitrogen fluoride (NₓF_{y}), oxygen (O₂), helium (He₂), silicide, or fluorine (F₂), or a mixture of at least two of the above gases.

15. The process of claim 13 wherein gases of the second high density plasma chemical vapor deposition process comprise nitrogen (N₂), nitrogen oxide (NₓO_{y}), nitrogen hydride (NₓH_{y}), nitrogen fluoride (NₓF_{y}), oxygen (O₂), helium (He₂), silicide, or fluorine (F₂), or a mixture of at least two of the above gases.

16. The process of claim 13 wherein gases of the first partial etching process comprise halogen gases, and the halogen gases react to form halogen ions in the chamber.

17. The process of claim 16 wherein gases of the first passivation process comprise hydrogen, and the hydrogen reacts with halogen ions to form halogen hydride to remove the halogen ions in the chamber.

18. The process of claim 13 wherein the gapfill process is a second high density plasma chemical vapor deposition, for forming a second dielectric layer on the first dielectric layer to fill the shallow trench.

19. The process of claim 13 wherein a high frequency radio frequency (HFRF) and low frequency radio frequency (LFRF) is provided in the chamber in performing multi-step depositing process.

20. The process of claim 18 wherein a frequency range of the HFRF and the LFRF of the first and second high density plasma chemical vapor deposition process is higher than a frequency range of the HFRF and the LFRF of the first partial etching process and the first passivation process.

21. The process of claim 19 wherein the frequency range of the HFRF of the first passivation process is higher than the frequency range of the HFRF of the first partial etching process.
